(19) United States
(12) Patent Application Publication
(10) Pub. No.: US 2026/0214825 A1
(43) Pub. Date: Jul. 23, 2026

(54) PCB FUSEBOX WITH RIBS AND SEAL

(71) Applicant: LEAR CORPORATION, Southfield, MI (US)

(72) Inventors: Jumar Rosaldo Ardiente, Busay Cebu City (PH); Alton Enric Fabre Bagares, Lapu-lapu City (PH); Oliver Jorley Enriquez Bejoc, Lapu-lapu City (PH); Gladys Cataraja Paquibot, Lapu-lapu City (PH)

(21) Appl. No.: 19/032,553

(22) Filed: Jan. 21, 2025

(51) Int. Cl. H05K 7/14; H05K 5/02; H05K 5/03

(52) U.S. Cl. CPC H05K 7/1427; H05K 5/0217; H05K 5/03

(57) ABSTRACT

A system includes a fusebox that comprises a housing base and a cover affixable on the housing base. The housing base includes side walls and a bottom wall that define an interior compartment, with an open top side over which the cover is affixable. There is a stand-off rib that extends from one of the side walls in the interior compartment. The stand-off rib defines a slot adjacent the bottom wall. There is a circuit board in the interior compartment. The circuit board includes connector terminals that extend through the one of the side walls. An edge portion of the circuit board extends into the slot, and the stand-off rib constrains the circuit board from moving in a direction toward the open side.

### BACKGROUND

Automobiles may include a power distribution fusebox mounted to the vehicle chassis. The fusebox typically includes a housing that has multiple power input ports and multiple output ports. There are one or more circuit boards mounted inside of the housing for controlling power distribution among the ports.

### BRIEF DESCRIPTION OF THE DRAWINGS

The various features and advantages of the present disclosure will become apparent to those skilled in the art from the following detailed description. The drawings that accompany the detailed description can be briefly described as follows.

FIG. 1 illustrates a power distribution system that includes a fusebox.

FIG. 2 illustrates a base of the fusebox with a circuit board in an installed position.

FIG. 3 illustrates the base of the fusebox with the circuit board in an uninstalled, pre-installation position.

FIG. 4 illustrates a sectioned side view of the base of the fusebox with the circuit board in a pre-installation position.

FIG. 5 illustrates a view at the bottom of the base of the fusebox.

FIG. 6 illustrates sectioned side view of the base of the fusebox with the circuit board in an installed position.

FIG. 7 illustrates a guide rib portion of the base of the fusebox.

FIG. 8 illustrates a perimeter slot and a seal in the base of the fusebox.

FIG. 9 illustrates a sectioned view through the slot and the seal, prior to engagement with the cover of the fusebox.

FIG. 10 illustrates a sectioned view through the slot and the seal, after engagement with the cover of the fusebox.

FIG. 11 illustrates a view of a portion of the seal.

FIG. 12 illustrates a sectioned view of the seal.

FIG. 13 illustrates another example seal.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

“One or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

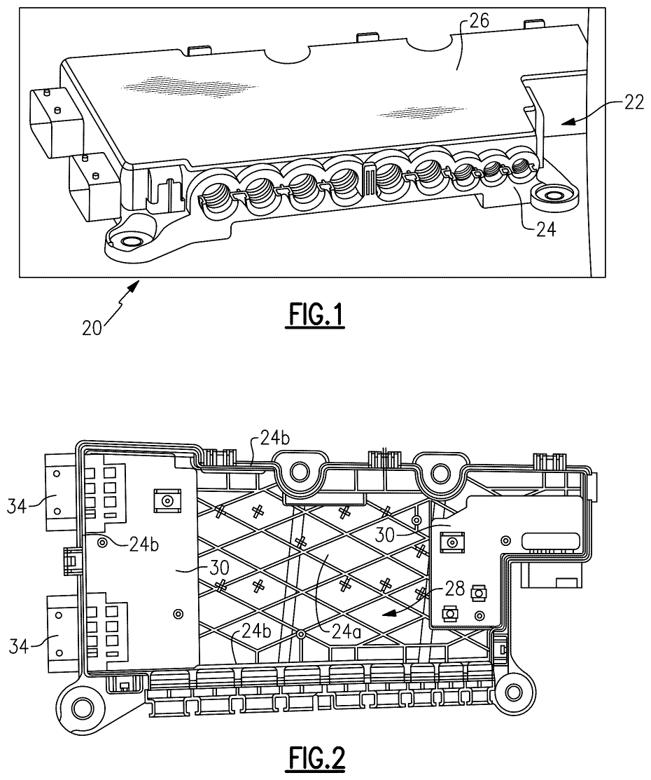

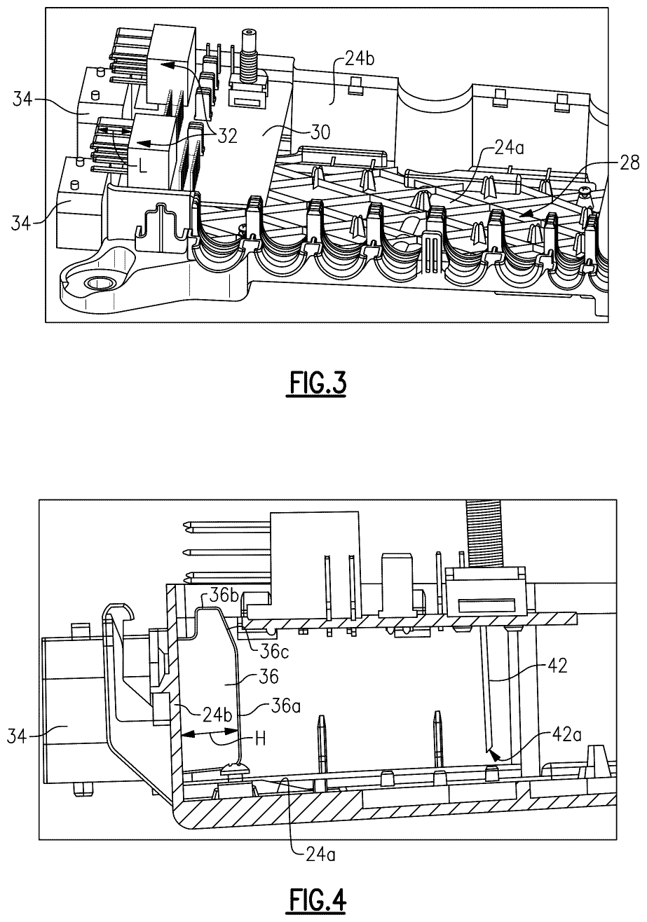

FIG. 1 illustrates a system 20 for use in an automobile. For example, although not limited, the system 20 in the illustrated example is operable for power distribution. The system 20 includes a fusebox 22 that has a housing base 24 and a cover 26 that is affixable on the base 24. For instance, the fusebox 22 has a clip or other locking mechanism that secures the cover 26 on the base 24. Referring also to FIGS. 2 and 3, which exclude the cover 26, the base 24 includes a bottom wall 24a and side walls 24b that define an interior compartment 28. Relative to FIG. 2, the left-most side wall 24b may be considered a “front” wall, and the top and bottom side walls 24b may be considered lateral walls. The base 24 has an open top opposite the bottom wall 24a, over which the cover 26 is affixable. There are one or more printed circuit boards 30 disposed in the interior compartment 28 (two in the example shown, but not limited thereto). For example, as shown in FIG. 3, the circuit board includes at least one group of connector terminals 32 (e.g., pins) which, when the circuit board 30 is in a fully installed position (FIG. 2), extend through a corresponding connector port 34. In FIG. 3 the circuit board is in a pre-installation position in which the board 30 has not yet been installed into the base 24.

FIG. 4 shows a sectioned side view with the circuit board 30 in a pre-installation position. The circuit board 30 is to be mounted on the bottom wall 24a in the interior compartment 28 with the connector terminals 32 extending through the connector port 34. Thus, in order to install the circuit board 30 into the fully installed position, the board 30 is lowered into the compartment 28 and then moved forwardly (in the direction that the connector terminals 32 are oriented, toward the front side wall 24b) such that the connector terminals extend through the port 34. A potential concern with such an installation process is that the connector terminals 32 can become damaged if they contact the side walls 24b when the circuit board 30 is lowered into the compartment 28.

In this regard, the base 24 includes one or more stand-off ribs 36 (FIG. 4) that extend from one of the side walls 24b in the interior compartment 28. For instance, the stand-off rib 36 is a relatively thin, elongated ridge that has a uniform height and extends along the interior side of the side wall 24b. The rib 36 defines a rib height H, which is the distance from the interior side of the front side wall 24b to the farthest away edge 36a of the rib 36. The rib 36 also has a top edge 36b that is generally parallel with the plane of the open top of the base 24 and a sloped edge 36c that is inclined at an oblique angle to the top edge 36b and slopes toward the bottom wall 24a.

The stand-off rib 36 ensures that the connector terminals 32 are spaced from the side wall 24b during installation. For example, the rib height H is greater than the length L (FIG. 3) of the connector terminals 32. Before the board 30 can be lowered into the compartment, the board 30 must be moved to pass beyond the edge 36a of the rib 36 before it can be lowered into the compartment. Until the board 30 moves past the edge 36a, the rib 36 blocks the board 30 from being lowered. For example, the board 30 is moved toward the compartment 28 along the top edge 36b and sloped edge 36c of the rib 36. During this movement, the board 30 may or may not be in contact with the rib 36, though contact may provide tactile feedback for manual installation. Once the board 30 passes beyond the interior edge 36a of the rib 36, the board 30 can be lowered into the compartment 28 toward the bottom wall 24a without the terminals contacting the side wall 24b.

The rib 36 does not extend all the way to the bottom wall 24a. Rather, as shown in FIG. 5, the rib 36 stops short and defines a slot 38 adjacent the bottom wall 24a. For instance, the slot 38 is a gap defined on a top side by the bottom edge 36d of the rib 36 and on a bottom side by the bottom wall 24a. Thus, once the board 30 is lowered into the compartment 28, the board 30 is then slid forward (in the direction that the connector terminals 32 are oriented) such that an edge of the board is received into the slot 38. During the sliding forward, the connector terminals 32 extend through the side wall 24b into the port 34, which is shown in FIG. 6. For instance, there are countersunk holes 40 in the side walls 24b through which the terminals 32 extend. Once in this fully installed position in the slot 38, the rib 36 constrains the board 30 from moving vertically upwards toward the open side of the base 24. That is, the rib 36, in addition to facilitating damage-free installation of the board 30, locks the board 30 in the fully installed position. The base 24 may have one or more additional stand-off ribs 36 on the lateral walls 26b, for aiding in installation of additional circuit boards.

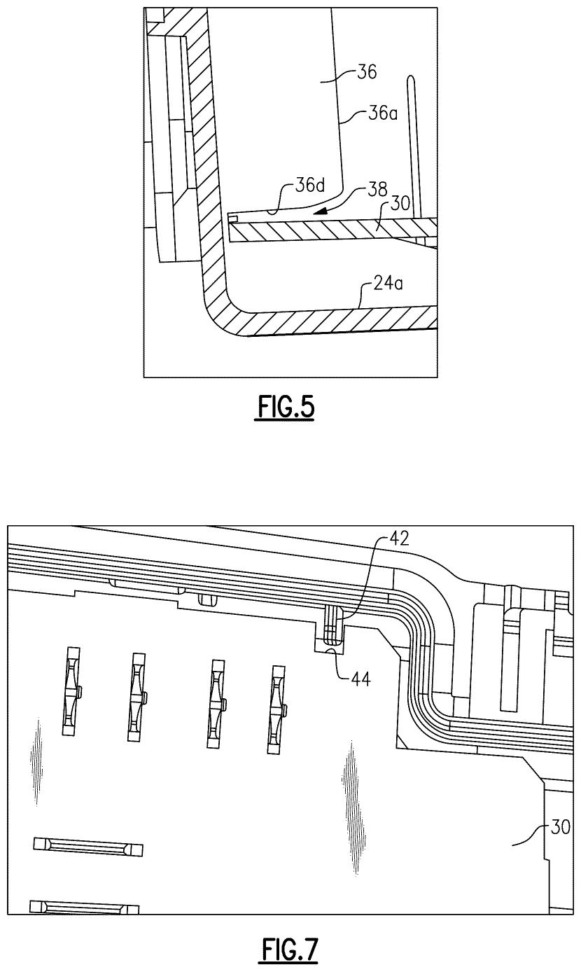

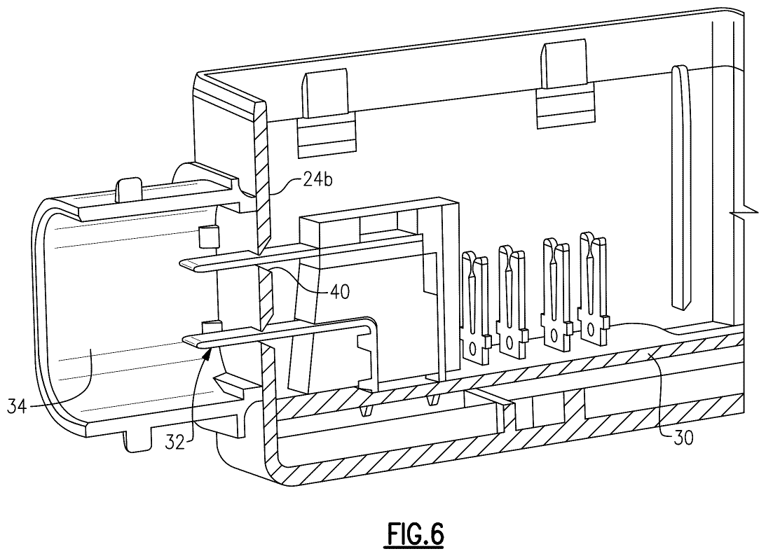

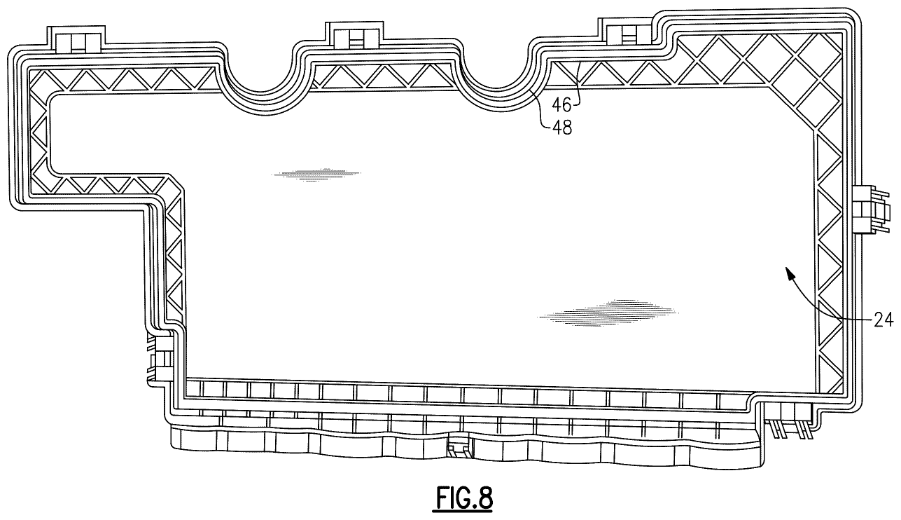

Referring to FIG. 4, the base 24 of the fusebox 22 may additionally include a guiderail rib 42 on one of the lateral side walls 24b. FIG. 7 shows a view looking down onto the circuit board 30. The circuit board 30 includes a circuit board slot 44, and the guiderail rib 42 extends into and interlocks with the slot 44. The guiderail rib 42 terminates at a guiderail rib bottom end short of the bottom wall 24a of the base 24. The guiderail rib 42 bottom end includes a sloped bearing surface 42a.

The guiderail rib 42 and slot 44 facilitate aligning and guiding the board 30 when the board is lowered into the compartment 28. For example, the guiderail rib 42 is positioned such that the slot 44 only aligns with the guiderail rib 42 when the board 30 is at a position that is past the edge 36a of the rib 36. When the board 30 is lowered into the compartment 28, the slot 44 and rib 42 ensure that the board 30 moves only vertically, and with little or no rotation. Once the board 30 is lowered past the bottom of the rib 42, the slot 44 slides off of the rib 42 and the board 30 is then free to be moved forwardly into the fully installed position. The face of the board 30 moves along the sloped bearing surface 42a, which facilitates guiding the board 30 while also preventing the board 30 from moving upwards.

The system 20 also has an associated method of assembly. For example, a method of assembly includes moving the circuit board 30 along a top portion 36b of the stand-off rib 36 toward the interior compartment 28 until the circuit board 30 passes beyond an interior edge 36a of the stand-off rib 36. The stand-off rib spaces the circuit board 30 from the side walls 24b such that the connector terminals 32 are spaced from an interior of the side walls 24b. The circuit board is then slid along the interior edge 36a of the rib 36 toward the bottom wall 24a until the board reaches the slot 38. An edge portion of the circuit board 30 is then slid into the slot 38. The slot 38 constrains the board 30 from moving in a direction toward the open side 24c, and the sliding also causes the connector terminals 32 to extend through the one of the side walls 24b into the connector port 34.

Turning now to FIG. 8 that shows the base 24 of the fusebox 22, the base 24 includes a perimeter slot 46 and a seal 48 disposed in the slot 46. The edge of the cover 26 is received in to the slot 46 and seals against the seal 48 to prevent ingress of moisture into the fusebox 22. It is to be appreciated that the slot 46 and seal 48 could alternatively be in the cover 26.

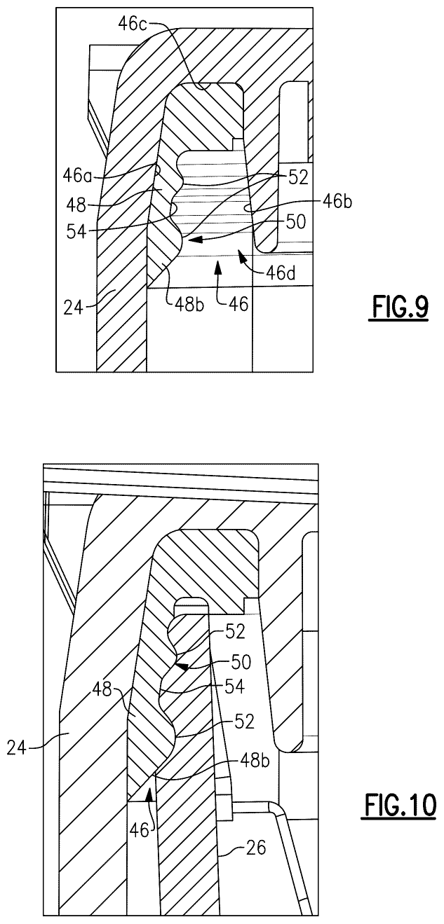

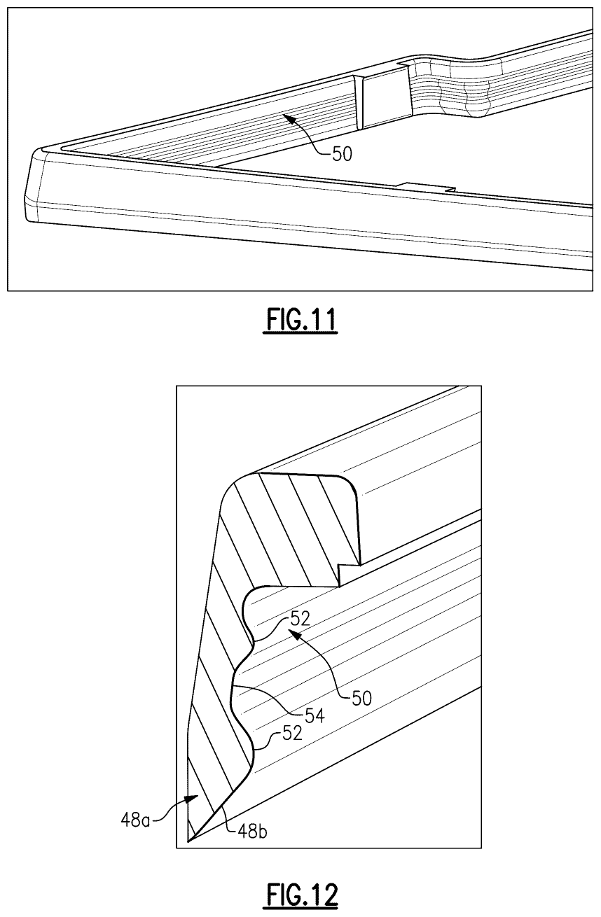

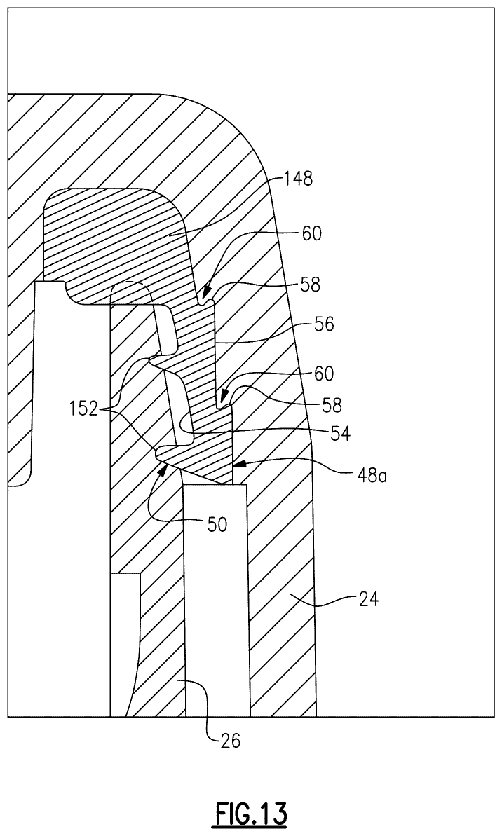

FIG. 9 is a sectioned view through the slot 46 and the seal 48; FIG. 10 is a sectioned view with the edge of the cover 26 received into the slot 46; FIG. 11 is a view of a portion of the seal 48; and FIG. 12 is a sectioned view of the seal 48. The slot 46 defines slot side walls 46a/46b, a slot bottom wall 46c that joins the slot side walls 46a/46b, and an open slot end 46d opposite the slot bottom wall 46. The elastomeric seal 48 lines the slot side wall 46a and the slot bottom wall 46c.

The seal 48 is an endless loop that is made of an elastomeric material, such as but not limited to, a thermoplastic elastomer. The seal 48 includes a seal surface 50, which is the side or sides of the seal 48 that seal against the mating component, i.e., against the sides and edge of the cover 26 in the illustrated example. The seal surface 50 has a plurality of protrusions 52 that are compressed against the cover 26 to effectuate sealing. In the illustrated example, the seal 48 has two protrusions 52 that facilitate sealing, but in additional examples the seal 48 may have more than two protrusions 52, such as three to five protrusions. The protrusions 52 give the seal surface 50 a waveform profile that has at least two peaks and a trough 54 in between the peaks.

The protrusions 52 compress when the cover 26 is received into the slot 46. When the protrusions 52 compress (deform), the sides of the protrusions laterally expand. The trough 54 provides an open area to accommodate at least a portion of the expansion, thereby allowing substantially uninhibited expansion, at least in the direction of the trough 54, which may reduce stresses in the seal 48 and thus enhance durability. The compression of the protrusions 52 also serves to maintain a sealing bias against the cover 26. That is, the elastomeric material of the compressed protrusions 52 rebounds from the compression and thus presses against the cover 26 to maintain sealing.

Additionally, the protrusions facilitate accommodation of dimensional tolerances in the fusebox 22. For example, in some instances, the base 24 and/or the cover 26 are formed from molded polymer and may warp under the processing conditions, leading to dimensional variance from par-to-part. However, the sealing bias of the protrusions 52 can take up some or all of the variances, ensuring good sealing even if there are variances. The elastomeric material also has a durometer that controls the sealing bias. For example, if the durometer is too low, the protrusions 52 may compress under low force and permit leakage, or permanently deform and permit leakage. On the other hand, if the durometer is too high, it may become difficult to compress the protrusions 52 and thereby increase the force necessary to insert the cover 26 into the slot 46. For example, the elastomeric material has a durometer of approximately 15 (Shore A) +/−5.

The protrusions 52 also provide a dual sealing scheme. For example, a first one of the protrusions 52 nearest the open end of the slot 46 serves as a primary seal that blocks most or all moisture ingress, while the second protrusion 52 farthest from the open end of the slot 46 serves as a secondary seal that blocks any moisture that might leak past the primary protrusion sealing.

The seal 48 also includes a leading tip 48a that has a sloped edge 48b. The sloped edge 48b is located at the open end of the slot 46 and slopes into the slot 46. The sloped edge serves to facilitate assembly by guiding the edge of the cover 26 into the slot 46. For instance, if the cover 26 does not exactly align with the slot during insertion into the slot 46, the edge of the cover 26 may slide along the sloped edge 48b to guide the edge of the cover 26 into the slot 46.

FIG. 13 illustrates another example seal 148 that is similar to the seal 48. In this example, the protrusions 152 are narrower and have a greater height in comparison to the protrusions 52 of the prior example. Additionally, a backside 56 of the seal located opposite the seal surface 50 includes protrusion undercuts 58 that define notches 60. The notches 60 interfit with corresponding notches on the housing base 24 to facilitate securing the seal 148 to the housing base 24.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from this disclosure. The scope of legal protection given to this disclosure can only be determined by studying the following claims.

What is claimed is:

1. A system comprising:
a fusebox, the fusebox comprising a housing base and a cover affixable on the housing base, the housing base comprising side walls and a bottom wall defining an interior compartment, an open top side over which the cover is affixable, and a stand-off rib extending from one of the side walls in the interior compartment, the stand-off rib defining a slot adjacent the bottom wall; and
a circuit board in the interior compartment, the circuit board comprising connector terminals extending through the one of the side walls, an edge portion of the circuit board extending into the slot, the stand-off rib constraining the circuit board from moving in a direction toward the open side.

2. The system as recited in claim 1, wherein a top portion of the stand-off rib includes sloped edge.

3. The system as recited in claim 1, wherein, along a direction away from the one of the side walls that the stand-off rib extends from, the sloped edge slopes toward the bottom wall.

4. The system as recited in claim 1, wherein a second one of the side walls includes a guiderail rib, the circuit board includes a circuit board slot, and the guiderail rib extends into the circuit board slot.

5. The system as recited in claim 4, wherein the guiderail rib terminates at a guiderail rib bottom end short of the bottom wall of the housing base.

6. The system as recited in claim 5, wherein the guiderail rib bottom end includes a sloped bearing surface.

7. The system as recited in claim 1, wherein one of the cover or the housing base includes a perimeter slot that engages the other of the housing base or the cover, and there is an elastomeric seal disposed in the perimeter slot, the elastomeric seal includes a seal surface having a plurality of protrusions compressed against the other of the housing base or the cover.

8. The system as recited in claim 7, wherein the elastomeric seal is an endless loop, is formed of thermoplastic elastomer, and has a Shore A durometer of 15+/−1 , and the plurality of protrusions includes first and second protrusions, with a trough therebetween, to permit lateral expansion of the first and second protrusions when the seal is under compression.

9. The system as recited in claim 8, wherein the elastomeric seal has a backside located opposite the first and second protrusions, the backside including protrusion undercuts that define notches.

10. A method comprising:
assembling a fusebox, the fusebox comprising a housing base, a cover affixable on the housing base, and a circuit board comprising connector terminals, the housing base comprising side walls, a bottom wall that defines an interior compartment, an open top side over which the cover is affixable, and a stand-off rib that extends from one of the side walls in the interior compartment, the stand-off rib defining a slot adjacent the bottom wall, wherein the assembling includes:
moving the circuit board along a top portion of the stand-off rib toward the interior compartment until the circuit board passes beyond an interior edge of the stand-off rib, the stand-off rib spacing the circuit board from the side walls such that the connector terminals are spaced from an interior of the side walls;
sliding the circuit board along the interior edge of the stand-off rib toward the bottom wall until the circuit board reaches the slot; and
sliding an edge portion of the circuit board into the slot, the slot constraining the circuit board from moving in a direction toward the open side, the sliding also causing the connector terminals to extend through the one of the side walls.

11. The method as recited in claim 10, wherein a top portion of the stand-off rib includes sloped edge.

12. The method as recited in claim 10, wherein, in a direction away from the one of the side walls that the stand-off rib extends from, the sloped edge slopes toward the bottom wall.

13. The method as recited in claim 10, wherein one of the cover or the housing base includes a perimeter slot, and there is an elastomeric seal disposed in the perimeter slot, the elastomeric seal includes a seal surface that has a plurality of protrusions.

14. The method as recited in claim 13, further comprising affixing the cover on the housing by bring the housing base and the cover together such that the one the cover or the housing base that does not include the perimeter slot is inserted into the perimeter slot to compress the plurality of protrusions.

15. A system comprising:
a fusebox, the fusebox comprising a housing base and a cover affixable on the housing base, the housing base and the cover enclosing an interior compartment, one of the cover or the housing base including a perimeter slot engaging the other of the housing base or the cover;
an elastomeric seal disposed in the perimeter slot, the elastomeric seal including a seal comprising a plurality of protrusions compressed against the other of the housing base or the cover; and
a circuit board in the interior compartment, the circuit board comprising connector terminals extending through a side wall of the housing base.

16. The system as recited in claim 15, wherein the elastomeric seal is an endless loop, formed of thermoplastic elastomer that has a Shore A durometer of 15+/−5 , the elastomeric seal has a backside located opposite the first and second protrusions, the backside includes protrusion undercuts that define notches.

17. The system as recited in claim 15, wherein the plurality of protrusions includes first and second protrusions, with a trough therebetween, to permit lateral expansion of the first and second protrusions when the seal is under compression.

18. The system as recited in claim 15, wherein the perimeter slot defines slot side walls, a slot bottom wall that joins the slot side walls, and an open slot side opposite the slot bottom wall, the elastomeric seal lining one of the slot side walls and the slot bottom wall, and wherein at the open slot side, the elastomeric seal includes a sloped edge.

19. The system as recited in claim 15, wherein the housing base includes side walls, a bottom wall that defines the interior compartment, an open top side over which the cover is affixable, and a stand-off rib that extends off of one of the side walls in the interior compartment, the stand-off rib defines a slot near the bottom wall.

20. The system as recited in claim 19, wherein an edge portion of the circuit board extends into the slot, and the stand-off rib constrains the circuit board from moving in a direction toward the open side.
